(19) United States
(12) Patent Application Publication
(10) Pub. No.: US 2021/0084786 A1
(43) Pub. Date: Mar. 18, 2021

(54) DEVICE HAVING AN ELECTRONICS UNIT AND A HOUSING, AND METHOD FOR PRODUCING SUCH A DEVICE

(71) Applicant: Robert Bosch GmbH, Stuttgart (DE)

(72) Inventors: Jens Bunert, Reutlingen (DE); Michael Roehrig, Bergisch Gladbach (DE)

(21) Appl. No.: 16/959,671

(22) PCT Filed: Nov. 20, 2018
(86) PCT No.: PCT/EP2018/081930

§ 371 Date: Aug. 12, 2020

(30) Foreign Application Priority Data
Jan. 12, 2018 (DE) 10 2018 200 512.5

(51) Int. Cl. H05K 5/06; H05K 9/00

(52) U.S. Cl. CPC H05K 5/065; H05K 2203/1316; H05K 9/0043

(57) ABSTRACT

A device having an electronics unit and a housing. The housing has at least one first housing part and a second housing part, which are developed and joined in such a way that the housing encloses the electronics unit, the first housing part and/or the second housing part being developed as a foil. A method for producing a device is also described.

### FIELD

The present invention relates to a device having an electronics unit and a housing.

### BACKGROUND INFORMATION

Conventionally, an electronics unit of a device may be enclosed in a housing in that the electronics unit is encapsulated in or extrusion-coated by plastic material.

Such devices typically have a solid housing, which is produced from a plastic material such as with the aid of an injection molding process. Also conventional are housings from metal which enclose the electronics unit accordingly. However, these metal housings may shield wireless communications units of the electronics unit.

### SUMMARY

The present invention relates to a device having an electronics unit and a housing.

An electronics unit is meant to describe that the electronics unit has electronic components such as a sensor unit and/or a processing unit and/or a memory element and/or a communications unit.

According to one aspect of the present invention, the housing has at least one first housing part and a second housing part, which are developed and joined in such a way that the electronics unit is enclosed by the housing, the first housing part and/or the second housing part being developed as a foil.

Such a housing having at least one housing part developed as a foil is typically referred to as blister packaging. It offers the advantage of allowing a housing part developed as a foil to be produced in a considerably more economical manner than, for instance, a housing part produced with the aid of an injection molding process. As a result, the costs of the device are able to be reduced accordingly, the costs including both the production and the material costs. The production costs could also be dependent on the set-up costs, such as the costs for the tool production. Despite these low costs, the housing parts developed as a foil offer a possibility of protecting the electronics unit from undesired external influences, e.g., from contamination or moisture. This makes it possible to achieve a protection rating certification (international protection code) according to IP54 or higher.

In addition, a housing part developed as a foil has considerably less weight than an injection-molded part so that, for example, transport costs of the device are able to be reduced.

Foil is to be understood as an object which is developed so that its thickness is lower by multiple orders of magnitude in relation to its width and in relation to its length. Such foils typically have a uniform thickness.

In one specific example development of the device according to the present invention, it is provided that the foil of the first housing part and/or the second housing part essentially has a thickness of between 0.1 mm and 5 mm. This offers the advantage that a foil of such a thickness is stable enough to protect the electronics unit from external negative effects yet still offers the corresponding advantages of reduced weight.

‘Essentially’ is to be understood as denoting that the foil of the respective housing part has a corresponding thickness throughout, which may deviate from this thickness in only a few small subregions.

According to one specific embodiment of the device according to the present invention, it is provided that the foil of the first housing part and/or the second housing part has a thinner development in at least one subregion than outside the subregion. This has the advantage that the reduced thickness makes it possible to increase the elasticity of the foil in this subregion. In addition, the optical transparency of the foil is able to be influenced in this manner. For example, a thin foil typically has greater optical transparency than a thicker foil.

According to one specific embodiment of the device according to the present invention, it is provided that the foil of the first housing part and/or the second housing part is a plastic foil which includes a biomaterial, in particular. This offers the advantage that a plastic foil does not electromagnetically shield a possible communications unit of the electronics unit. When a biomaterial is used, the device may additionally also be used in areas where special preconditions exist with regard to the employed material. For instance, this may be the case in the food sector where the material has to be nontoxic, for example.

According to one specific embodiment of the device according to the present invention, it is provided that the first housing part and/or the second housing part has/have an adhesive material and in particular a one-sided or double-sided adhesive coating.

This has the advantage, for example, that the housing parts are able to be adhesively joined to each other. In this context, such an adhesive connection is able to be realized in a very simple and economical manner. Another advantage, for instance, is that the electronics unit may be connected to one of the housing parts by the adhesive material or else the housing part is able to be mounted on an object with the aid of the adhesive material, which therefore allows for an uncomplicated yet stable affixation of the electronics unit or the device. A foil provided with an adhesive coating may be an adhesive tape, for instance.

According to one specific embodiment of the device according to the present invention, it is provided that the first housing part and/or the second housing part has/have an essentially or regionally optically transparent development. This has the advantage that optical radiation from the interior of the housing is able to reach the outside and/or reach the interior of the housing from the outside. For instance, this makes it possible for a potential user to view the interior of the housing. For example, a user is thereby able to visually perceive information that may be emitted by a display element of the electronics unit.

‘Optical transparency’ is meant to describe that optical radiation is able to penetrate the material. The optical radiation having the ability to penetrate the material in particular has a predefined wavelength range in this case. However, it is also possible that radiation of any wavelength is able to penetrate the material. The optical transparency, for example, is able to be influenced by the thickness of the respective housing part. As an alternative or in addition, for instance, the optical transparency may also be influenced by dying or coating the corresponding housing part e.g., using printing.

According to one specific embodiment of the device according to the present invention, it is provided that the electronics unit is developed as a data logger. The device according to the present invention is advantageously able to be used for monitoring an object in that the device is placed in an object or on the object or in an environment of the object. For this purpose, the correspondingly developed electronics unit particularly has a sensor unit for sensing at least one of the environment parameters that are acting on the object as well as a memory element for storing the at least one sensed environment parameter. Based on the sensed and stored environment parameters, it is possible to check whether the object was properly handled during transport, for instance. Depending on the specific embodiment of the sensor unit, for example, it is possible to check whether the object was subjected to jerks or whether threshold values for moisture and/or temperature were exceeded.

The low weight of the housing compared with conventional housing has the additional advantage that lower damping from external influences is acting on the electronics unit, so that the sensing of the environment parameters that are acting on an object is affected to a lesser degree.

In addition, the present invention relates to a method for producing a device according to the present invention. In accordance with an example embodiment of the present invention, the method has at least the following method steps:
a) Producing at least one first housing part and a second housing part, the first housing part and/or the second housing part being produced from a foil;
b) Producing an electronics unit;
c) Joining the at least one first housing part and the second housing part in such a way that a housing is produced which encloses the electronics unit.

This has the advantage that a housing part produced from a foil is able to be produced in a much more economical manner than a housing part produced, for example, by an injection molding process. The costs of the device are therefore able to be reduced accordingly, the costs relating both to the production costs and the material costs. Nevertheless, the housing parts produced from a foil offer a possibility for protecting the electronics unit from undesired external influences, such as contamination or moisture. A protection rating certification (international protection code) according to IP54 or higher is therefore able to be achieved. In addition, a housing part produced as a foil has a considerably lower weight so that transport costs of the device, for example, are able to be reduced.

A production of the housing parts means that the housing parts are formed in such a way that the electronics unit is correspondingly enclosed by the housing during the subsequent joining of the housing parts.

Producing the electronics unit, for instance, is meant to denote that a circuit board is fitted with corresponding electronic components. In addition, testing of the electronics unit may take place in the process as well.

According to one specific development of the method according to the present invention, it is provided that the first housing part and/or the second housing part is/are produced by deep-drawing of the foil, in particular with the aid of thermoforming, in method step a. This offers the advantage that such a method step is able to be carried out especially quickly and easily. In particular, a large number of devices according to the present invention is therefore able to be produced in an economical manner because the costs for the appropriately developed tool equipment are low and arise only once.

According to one specific development of the method according to the present invention, it is provided that a further method step d is carried out, in which the foil of the first housing part and/or the second housing part is cut to size. This offers the advantage that the housing is able to be correspondingly minimized in its size.

According to one development of the method according to the present invention, it is provided that the first housing parts and the second housing parts are irreversibly joined in method step c, in particular by bonding or in particular by welding, especially preferably by thermo-welding and/or especially preferably by ultrasonic welding. This has the advantage of constituting an easy possibility for connecting the two housing parts to each other. Such a connection is very stable and reliably seals the electronics unit with respect to the outside of the housing.

### BRIEF DESCRIPTION OF THE DRAWINGS

FIG. 1 shows an exemplary embodiment of a device according to the present invention.

FIG. 2 shows an exemplary embodiment of a method according to the present invention for the production of a device according to the present invention.

### DETAILED DESCRIPTION OF EXAMPLE EMBODIMENTS

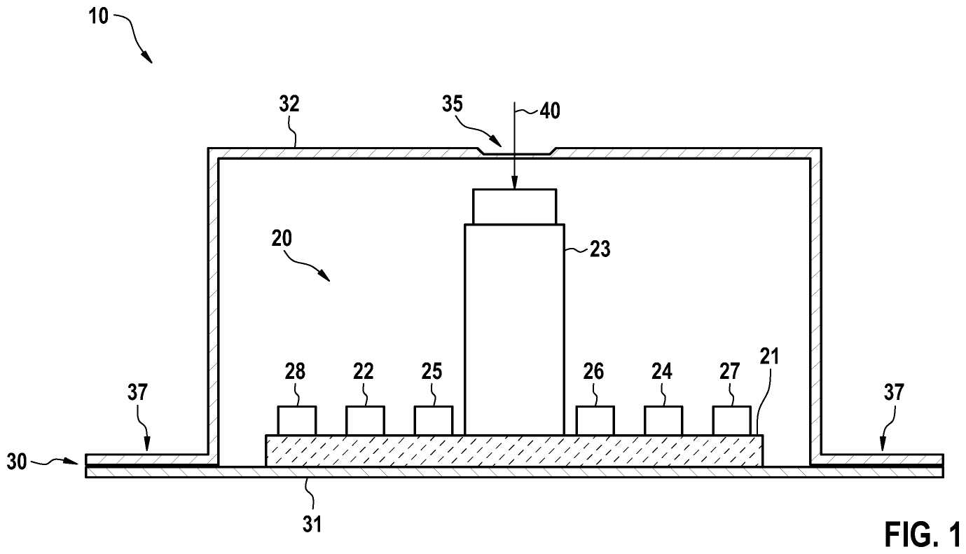

FIG. 1 shows an exemplary embodiment of a device according to the present invention. Shown is a device 10 which includes an electronics unit 20 and a housing 30.

Housing 30 encompasses a first housing part 31 and a second housing part 32. First housing part 31 and second housing part 32 are developed and joined in such a way that housing 30 encloses electronics unit 20. For example, first housing part 31 is glued and/or welded to second housing part 32 in edge regions 37 of housing 30. In addition, first housing part 31 and second housing part 32 are developed as a foil. However, as an alternative it is also possible that only one of housing parts 31, 32 is developed as a foil. For example, this foil may particularly be a plastic foil, which preferably has a thickness of between 0.1 mm and 5 mm. In a particularly preferred manner, the plastic foil includes a biomaterial. The foil of first housing part 31 may have a thinner development in a subregion 35 than outside subregion 35. Moreover, the foil of first housing part 31 and/or second housing part 32 may at least regionally have an optically transparent development. This is able to be achieved in that the foil, e.g., as in subregion 35 of the foil of first housing part 31, has a thin development such that an optical transparency of the foil is achieved. As an alternative, for instance, the foil may have a material composition that is transparent to optical radiation, in particular within a predefined wavelength range. As an alternative, the foil may also be regionally coated or imprinted in such a way that housing part 31, 32 has a corresponding optical transparency in the corresponding region.

Electronics unit 20, for instance, has a circuit board 21 on which corresponding electronic components are situated. These electronic components, for example, may be a sensor unit 22 and/or a switching element 23 and/or an energy supply unit 24 and/or a communications unit 25.

Sensor unit 22, for instance, may include an acceleration sensor and/or a temperature sensor and/or a magnetic field sensor and/or a moisture sensor and/or a light sensor for sensing corresponding environment parameters such as the humidity or vibrations.

Switching element 23 is able to be embodied as a push button, for example, and be placed in such a way that an actuation of switching element 23 in an operating direction 40 from outside the housing is possible. Toward this end, switching element 23 may be disposed underneath subregion 35 in which first housing part 31 is more elastic on account of its lower thickness than outside of subregion 35.

Energy supply element 24, for instance, may include an energy store and/or an energy harvesting unit. The energy store may be equipped with a battery and/or a capacitor, for example. In particular, communications unit 25 is able to be embodied as a wireless communications unit, e.g., as a WLAN unit and/or a Bluetooth and/or a LoRa unit and/or as a mobile radio unit.

In addition, for instance, electronics unit can include a processing unit 26 and/or a memory element 27 and/or a display element 28. For example, processing unit 26 is able to be embodied as a microcontroller and in particular may also have an already integrated memory element 27.

Display element 28, for example, is able to include an illumination device or a display.

By fitting circuit board 21 with the corresponding electronic components, electronics unit 20 may be developed as a data logger, which is able to sense and store environment parameters.

To allow electronics unit 20 to be used as a data logger requires especially at least sensor unit 22 and memory element 27. Device 10 is thereby able to be used for monitoring an object. This object can be a transport good, for example.

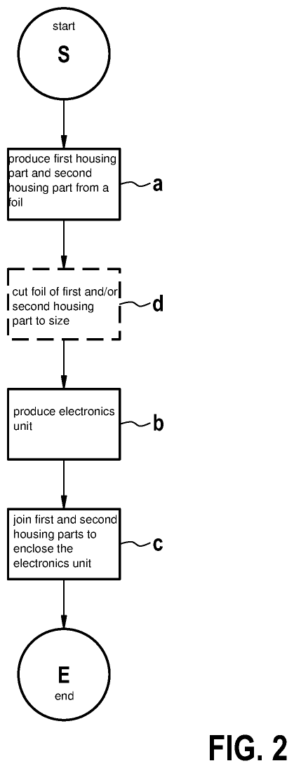

FIG. 2 shows an exemplary embodiment of a method according to the present invention for producing a device according to the present invention.

In the method according to this exemplary embodiment, at least one first housing part 31 and a second housing part 32 are produced in a method step a after start S, first housing part 31 and/or second housing part 32 being produced from a foil. In particular, the first and second housing parts are produced from the same foil and thus have identical material properties. First housing part 31 and/or second housing part 32 is/are able to be produced by deep-drawing of the foil, in particular with the aid of thermoforming.

Subsequent to method step a, an electronics unit 20 is produced in a method step b. This is accomplished in that a circuit board 21 is fitted with corresponding electronic components, for instance.

Next, in a method step c, the at least one first housing part 31 and second housing part 32 are joined in such a way that a housing 30 is produced which encloses electronics unit 20. In the process, first housing part 31 and second housing part 32 are irreversibly joined, in particular by bonding and/or welding, especially preferably by thermo-welding and/or ultrasonic welding.

Optionally, a method step d is additionally carried out between method step a and method step b. In method step d, the foil of first housing part 31 and/or second housing part 32 is cut to size.

The sequence of method steps a, b and d is able to be switched as desired. In addition, method step d may also be carried out only after method step c.

1-11. (canceled)

12. A device comprising:
an electronics unit; and
a housing having at least one first housing part and a second housing part, the at least one first housing part and the second housing part being configured and joined in such a way that the housing encloses the electronics unit, wherein the first housing part and/or the second housing part are formed from a foil.

13. The device as recited in claim 12, wherein the foil of the at least one first housing part and/or the second housing part has a thickness of between 0.1 mm and 5 mm.

14. The device as recited in claim 12, wherein the foil of the at least one first housing part and/or the second housing part has a thinner development in at least one subregion than outside the subregion.

15. The device as recited in claim 12, wherein the foil of the first housing part and/or the second housing part is a plastic foil which includes a biomaterial.

16. The device as recited in claim 12, wherein the at least one first housing part and/or the second housing part has an adhesive material.

17. The device as recited in claim 16, wherein the adhesive material is a one-sided or double-sided adhesive coating.

18. The device as recited in claim 12, wherein the at least one first housing part and/or the second housing part has a regionally optically transparent development.

19. The device as recited in claim 12, wherein the electronics unit is a data logger.

20. A method for producing a device, comprising the following steps:
a. producing at least one first housing part and a second housing part, the first housing part and/or the second housing part being produced from a foil;
b. producing an electronics unit;
c. joining the at least one first housing part and the second housing part in such a way that a housing is produced which encloses the electronics unit.

21. The method as recited in claim 20, wherein in step a, the at least one first housing part and/or the second housing part is produced by deep-drawing of the foil using thermoforming.

22. The method as recited in claim 20, further comprising the following step:
d. cutting the foil of the at least one first housing part and/or the second housing part to size.

23. The method as recited in claim 20, wherein in step c, the at least one first housing part and the second housing part are irreversibly joined by bonding and/or by welding.

24. The method as recited in claim 20, wherein in step c, the at least one first housing part and the second housing part are irreversibly joined by thermo-welding and/or by ultrasonic welding.
